(19) United States
(12) Patent Application Publication
(10) Pub. No.: US 2024/0210471 A1
(43) Pub. Date: Jun. 27, 2024

(54) ELECTRONIC DEVICE AND METHOD OF TESTING ELECTRONIC DEVICE

(71) Applicant: Samsung Electronics Co., Ltd., Suwon-si (KR)

(72) Inventor: Seaeun Park, Suwon-si (KR)

(21) Appl. No.: 18/338,471

(22) Filed: Jun. 21, 2023

(30) Foreign Application Priority Data
Dec. 26, 2022 (KR) 10-2022-0185065

(51) Int. Cl. G01R 31/3185; G06F 30/333

(52) U.S. Cl. CPC G01R 31/318547; G01R 31/318591; G06F 30/333

(57) ABSTRACT

Disclosed is a method of testing an electronic device, which includes receiving, by a computer, a circuit layout, generating, by the computer, a design for test (DFT) layout from the circuit layout, generating, by the computer, a test pattern by using an electronic design automation (EDA) tool, based on the DFT layout, and generating, by the computer, a hybrid layout from the DFT layout, and the electronic device manufactured by using the hybrid layout is tested by using the test pattern.

### CROSS-REFERENCE TO RELATED APPLICATIONS

This application claims priority under 35 U.S.C. § 119 to Korean Patent Application No. 10-2022-0185065 filed on Dec. 26, 2022, in the Korean Intellectual Property Office, the disclosure of which is incorporated by reference herein in its entirety.

### BACKGROUND

Embodiments of the present disclosure described herein relate to an electronic device, and more particularly, relate to an electronic device capable of being tested in structure without a scan chain and a method of testing an electronic device.

After manufacturing an electronic device, a test may be performed to determine whether the electronic device normally operates. The test may include a functional test and a structural test.

The functional test may allow the electronic device to repeatedly perform a specified function for the purpose of determining whether the electronic device normally performs the specified function. According to the functional test, various cases should be tested based on an input value range and based on events possible in the electronic device. In practice, in the functional test, all the possible cases may not be tested, but only some representative cases that are regarded to be important experientially may be tested. In this case, in the functional test, a test coverage capable of finding defects of the electronic device may be relatively low.

According to the structural test, whether each component of the electronic device operates normally without a defect may be tested. The structural test may directly check signal values of wires through which signals are transferred. Because a relatively small number of cases are tested in the structural test, the structural test may have relatively high (or complete) test coverage. However, the structural test requires separate components for testing, such as a scan chain, which increases the amount of overhead.

### SUMMARY

Embodiments of the present disclosure provide an electronic device capable of being tested in structure (i.e., in situ) without a scan chain, and a method of testing an electronic device.

According to an embodiment, a method of testing an electronic device includes receiving, by a computer, a circuit layout, generating, by the computer, a design for test (DFT) layout from the circuit layout, generating, by the computer, a test pattern by using an electronic design automation (EDA) tool, based on the DFT layout, and generating, by the computer, a hybrid layout from the DFT layout, and the electronic device manufactured by using the hybrid layout is tested by using the test pattern.

According to an embodiment, an electronic device includes a first pad, a second pad, and a first circuit that receives a test pattern through the first pad and outputs a test result corresponding to the test pattern through the second pad, in a test mode. The first circuit includes at least one bypass storage element. In the test mode, the at least one bypass storage element bypasses an input signal to an output. In a specified function mode, the at least one bypass storage element stores an input signal, and outputs the input signal to an output. The test pattern is generated in a process of generating a layout of the electronic device such that a structural test of the first circuit is performed.

According to an embodiment, an electronic device includes a plurality of memory banks, a gating circuit that connects one of the plurality of memory banks to an external device in response to a bank address, and control logic that receives a command and an address from the external device, provides a bank address of the address to the gating circuit, and provides a row address of the address to the plurality of memory banks. The control logic includes repair logic. The repair logic receives a first subset of bits among a plurality of bits of the row address, compares the first subset of bits with repair bits, and replaces the first subset of bits with redundant bits corresponding to the repair bits, when the first subset of bits are matched with the repair bits. The repair logic includes a first circuit configured to receive a test pattern as the first subset of bits and outputs a test result corresponding to the test pattern, in a test mode. The first circuit includes at least one bypass storage element. In the test mode, the at least one bypass storage element bypasses an input signal to an output. In a specified function mode, the at least one bypass storage element stores an input signal, and outputs the input signal to an output. The test pattern is generated in a process of generating a layout of the electronic device such that a structural test of the first circuit is performed.

### BRIEF DESCRIPTION OF THE FIGURES

The above and other objects and features of the present disclosure will become apparent by describing in detail embodiments thereof with reference to the accompanying drawings, wherein like reference numerals (when used) indicate corresponding elements throughout the several views, and in which:

FIG. 1 is a block diagram illustrating at least a portion of an example electronic device, according to an embodiment of the present disclosure;

FIG. 2 is a diagram illustrating at least a portion of an example method of testing an electronic device, according to an embodiment of the present disclosure;

FIGS. 3A to 3D are diagrams illustrating examples of a source layout, according to an embodiment of the present disclosure;

FIG. 4 is a diagram illustrating at least a portion of an example method in which an electronic device generates a DFT layout from a source layout, according to an embodiment of the present disclosure;

FIGS. 5A to 5D are diagrams illustrating examples of design for test (DFT) layouts generated from FIGS. 3A to 3D.

FIG. 6 is a diagram illustrating at least a portion of an example method in which an electronic device generates a first test pattern, according to an embodiment of the present disclosure;

FIG. 7 is a diagram illustrating at least a portion of an example method in which an electronic device generates a second test pattern, according to an embodiment of the present disclosure;

FIG. 8 is a diagram illustrating at least a portion of an example method in which an electronic device generates a hybrid layout from a DFT layout, according to an embodiment of the present disclosure;

FIGS. 9A to 9D are diagrams illustrating examples of hybrid layouts generated from FIGS. 5A to 5D.

FIG. 10 is a diagram illustrating at least a portion of a first example method of testing an electronic device manufactured based on a hybrid layout, according to an embodiment of the present disclosure;

FIG. 11 is a diagram illustrating at least a portion of a second example method of testing an electronic device manufactured based on a hybrid layout, according to an embodiment of the present disclosure;

FIG. 12 is a diagram illustrating an example of an electronic device manufactured based on a hybrid layout, according to an embodiment of the present disclosure;

FIG. 13 is a diagram illustrating an example of repair logic, according to an embodiment of the present disclosure;

FIG. 14 is a diagram illustrating an example of a fifth source layout, according to an embodiment of the present disclosure;

FIG. 15 is a diagram illustrating an example of a fifth DFT layout, according to an embodiment of the present disclosure; and

FIG. 16 is a diagram illustrating an example of a fifth hybrid layout, according to an embodiment of the present disclosure.

### DETAILED DESCRIPTION

Hereinafter, embodiments of the inventive concept will be described in detail with reference to the accompanying drawings.

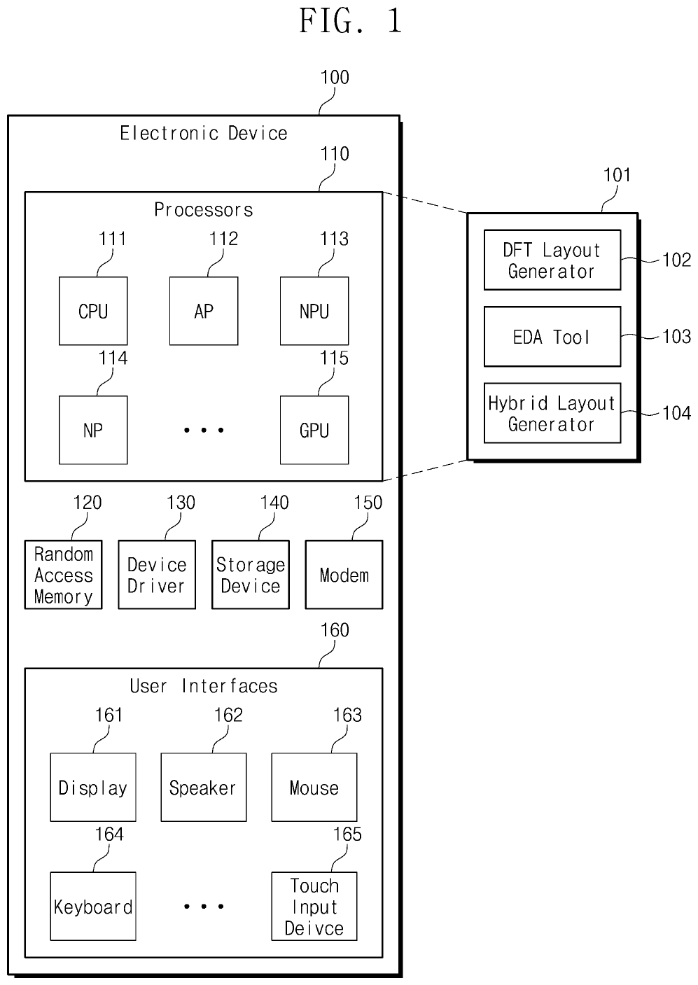

FIG. 1 is a block diagram illustrating at least a portion of an example electronic device 100, according to an embodiment of the present disclosure. Referring to FIG. 1, the electronic device 100 may include one or more processors 110, a random access memory 120, a device driver 130, a storage device 140, a modem 150, and one or more user interfaces 160.

The processors 110 may include, for example, at least one general-purpose processor such as a central processing unit (CPU) 111 or an application processor (AP) 112. Also, the processors 110 may further include at least one special-purpose processor such as a neural processing unit (NPU) 113, a neuromorphic processor (NP) 114, or a graphics processing unit (GPU) 115. The processors 110 may include two or more homogeneous processors; that is, although depicted as separate functional blocks, it is to be appreciated that two or more of the processors 111 through 115 may be combined into a single processor configured to perform the functions of the combined processors.

At least one of the processors 110 may drive a layout generation module 101. For example, the layout generation module 101 may be implemented in the form of instructions (or codes) that are executed by at least one of the processors 110. In this case, the at least one processor may load the instructions (or codes) of the layout generation module 101 into the random access memory 120.

For another example, at least one (or at least another) processor of the processors 110 may be configured to implement the layout generation module 101. For example, the at least one processor may be a dedicated hardware processor that implements functions of the layout generation module 101, thereby avoiding the need to download instructions or code into the random access memory 120 or other storage device.

The random access memory 120 may be used as a working memory of the processors 110 and may be used as a main memory or a system memory of the electronic device 100. The random access memory 120 may include a volatile memory such as a dynamic random access memory or a static random access memory, or a nonvolatile memory such as a phase-change random access memory, a ferroelectric random access memory, a magnetic random access memory, or a resistive random access memory.

The random access memory 120 may store images that are necessary for the learning of the layout generation module 101. For example, the random access memory 120 may receive images from the storage device 140 or may receive images from an external device (e.g., a database, not explicitly shown) through the modem 150. The term “external device,” as may be used herein, is intended to refer broadly to any device that resides externally (i.e., outside) relative to the electronic device 100. More generally, any device (or functional block, circuit or module) that is outside of (i.e., external relative to) a given device, functional block, circuit or module may be considered an “external device.”

The device driver 130 may control the following peripheral devices depending on a request of the processors 110: the storage device 140, the modem 150, and the user interfaces 160. The storage device 140 may include a stationary storage device such as, but not limited to, a hard disk drive or a solid-state drive, or a removable storage device such as an external hard disk drive, an external solid-state drive, a flash drive, or a removable memory card.

The storage device 140 may store images that are necessary for the learning of the layout generation module 101. The images stored in the storage device 140 may be loaded into the random access memory 120 and may be used for the learning of the layout generation module 101.

The modem 150 may provide remote communication with the external device. The modem 150 may perform wired or wireless communication with the external device. The modem 150 may communicate with the external device based on at least one of various communication schemes or protocols, such as, for example, Ethernet, wireless-fidelity (Wi-Fi), long term evolution (LTE), and 5th generation (5G) mobile communication. The modem 150 may receive images, which are necessary for the learning of the layout generation module 101, from the external device, for example, the database or other storage device. The modem 150 may load the received images into the random access memory 120.

The user interfaces 160 may receive information from a user and may provide information to the user. The user interfaces 160 may include at least one user output interface, such as, for example, a display 161 or a speaker 162, and/or at least one user input interface, such as, for example, a mouse 163, a keyboard 164, or a touch input device 165.

The instructions (or codes) of the layout generation module 101 may be received through the modem 150 and may be stored in the storage device 140. The instructions (or codes) of the layout generation module 101 may be stored in a removable storage device, and the removable storage device may be coupled to the electronic device 100. The instructions (or codes) of the layout generation module 101 may be loaded and supplied to the random access memory 120 from the storage device 140.

The layout generation module 101 may include a design for test (DFT) layout generator 102, an electronic design automation (EDA) tool 103, and a hybrid layout generator 104. The DFT layout generator 102 may generate a DFT layout from a source (i.e., circuit) layout of an electronic device to be manufactured, based on a given rule (e.g., a design rule check (DRC) output corresponding to the electronic device to be manufactured). The source layout may refer to a layout generated to perform specified functions that the electronic device intends to perform. The DFT layout may include constituent elements added to the source layout for the purpose of the structural test or elements converted from existing constituent elements.

The EDA tool 103 may generate test patterns appropriate for performing the structural test, based on a structure indicated by the DFT layout. For example, the EDA tool 103 may select two or more test targets and may generate two or more test patterns for each of the respective two or more test targets.

The hybrid layout generator 104 may generate a hybrid layout from the DFT layout. The hybrid layout generator 104 may generate the hybrid layout by removing or converting components associated with a scan chain from the DFT layout. As will be understood by those skilled in the art, the term “scan chain” typically refers to a technique used in design for testing. An objective in scan chain testing is to make testing easier by providing a simple way to set and observe every flip-flop in a combinational logic block of an integrated circuit. The hybrid layout may be considered “hybrid,” as the word is used herein, at least in terms of providing an electronic device supporting the structural test without including components associated with the scan chain for the structural test.

The layout generation module 101 may allow the EDA tool 103 to generate a test pattern by generating the DFT layout from the source layout. As the layout generation module 101 generates the hybrid layout from the DFT layout, the layout generation module 101 may generate a hybrid layout of an electronic device, in which the structural test is possible without an overhead of constituent elements associated with the scan chain, by using the test pattern generated from the DFT layout in the process of generating the hybrid layout.

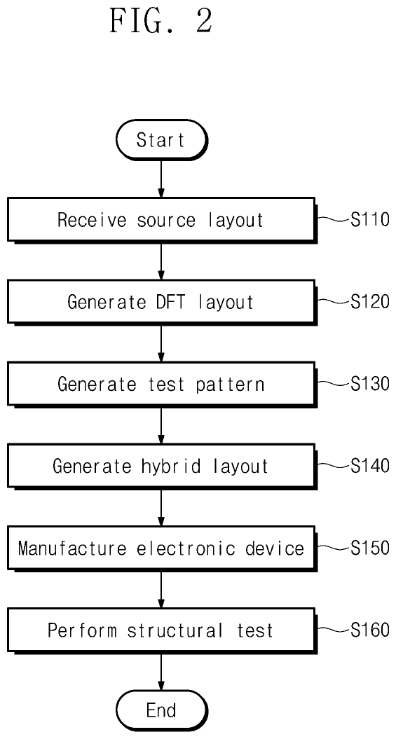

FIG. 2 is a diagram illustrating at least a portion of an example method of testing an electronic device, according to one or more embodiments. Referring to FIGS. 1 and 2, in operation S110, the electronic device 100 may receive a source layout relating to an electronic device under test (i.e., to be manufactured). The source layout may refer to a layout generated to perform specified functions that the electronic device to be manufactured intends to perform. For example, the electronic device 100 may receive a functional layout through the modem 150 or through the storage device 140 coupled to the electronic device 100 as a removable storage device.

In operation S120, the electronic device 100 may generate a DFT layout. For example, the DFT layout generator 102 of the layout generation module 101 driven by the electronic device 100 may generate the DFT layout from the source layout by converting a constituent element of at least one type, designated to perform a specified function in the source layout, into a constituent element appropriate for the DFT or by adding a constituent element for the DFT. The DFT layout may be generated from the source layout such that the structural test is performed based on the scan chain.

In operation S130, the electronic device 100 may generate a test pattern. For example, the EDA tool 103 of the layout generation module 101 driven by the electronic device 100 may generate two or more test patterns respectively corresponding to two or more test targets, based on the DFT layout.

In an embodiment, the EDA tool 103 may refer to a tool organized to generate test patterns for determining whether various test targets are defective, in an electronic device including a scan chain-based test structure. The EDA tool 103 may be commercialized in various forms by various manufacturers, and thus, the detail description associated with the EDA tool 103 will be omitted. In an embodiment, various test targets may at least include a signal defect due to a stuck-at fault (e.g., stuck bit) and/or transmission delay. As the term may be used herein, a “stuck-at fault” is a particular fault model often used by fault simulators and automatic test pattern generation (ATPG) tools to mimic a manufacturing defect within an integrated circuit. Individual signals and pins that are stuck at a particular logic level (e.g., “1” or “0”) may be indicative of a defect, such as a short or open circuit, in an associated signal path.

In an embodiment, because the DFT layout is generated to perform the scan chain-based structural test, the EDA tool 103 may generate test patterns from the DFT layout.

In operation S140, the electronic device 100 may generate a hybrid layout. For example, the hybrid layout generator 104 of the layout generation module 101 driven by the electronic device 100 may generate the hybrid layout by converting constituent elements of the DFT layout associated with the scan chain into constituent elements not associated with the scan chain or removing the constituent elements associated with the scan chain from the DFT layout.

In an embodiment, in the process of generating the hybrid layout from the DFT layout, the electronic device 100 may maintain some of the constituent elements converted in the process of generating the DFT layout from the source layout. The maintained constituent elements may support that an electronic device being a manufacturing target performs the structural test without constituent elements associated with the scan chain.

In operation S150, electronic device manufacturing equipment (not explicitly illustrated, but implied) may manufacture the electronic device being a manufacturing target based on the hybrid layout. Because the hybrid layout is different from the source layout, the structure of the manufactured electronic device may be different from that manufactured by using the source layout. Also, because the hybrid layout is different from the DFT layout, the structure of the manufactured electronic device may be different from that manufactured by using the DFT layout.

Even though the test pattern is generated to perform the test in the DFT layout, the constituent elements maintained in the hybrid layout may make it possible to perform the test even in the manufactured electronic device.

In operation S160, electronic device test equipment (e.g., advanced or automated test equipment (ATE)) may perform the structural test. For example, the test equipment may test the electronic device manufactured by the manufacturing equipment by using the test equipment generated in the DFT layout. For example, the test of the manufactured electronic device may be performed at a wafer level.

In an embodiment, the scan chain-based test may be performed by applying, at the test equipment, various signals (e.g., scan enable signals and scan input signals) to the manufactured electronic device through pads. In contrast, the electronic device manufactured based on the hybrid layout may be tested by an internally set policy except that a test pattern is input through pads.

For example, the manufactured electronic device may include registers that store policies for performing the test. The test equipment may perform the structural test of the manufactured electronic device by setting policies for the test in the registers and inputting the test pattern through pads.

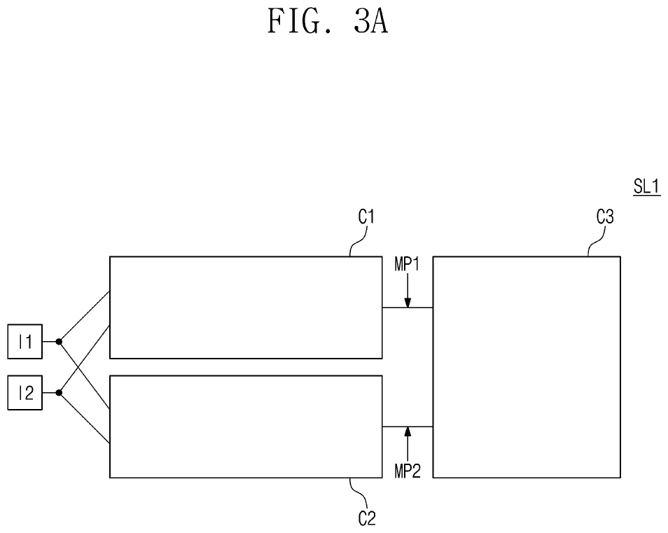

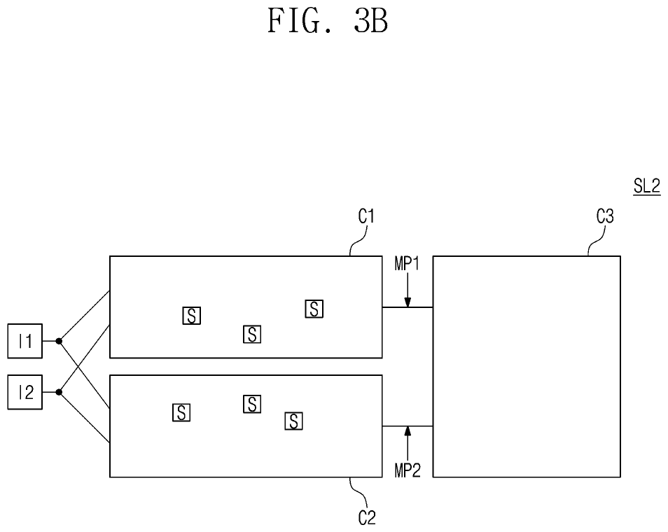

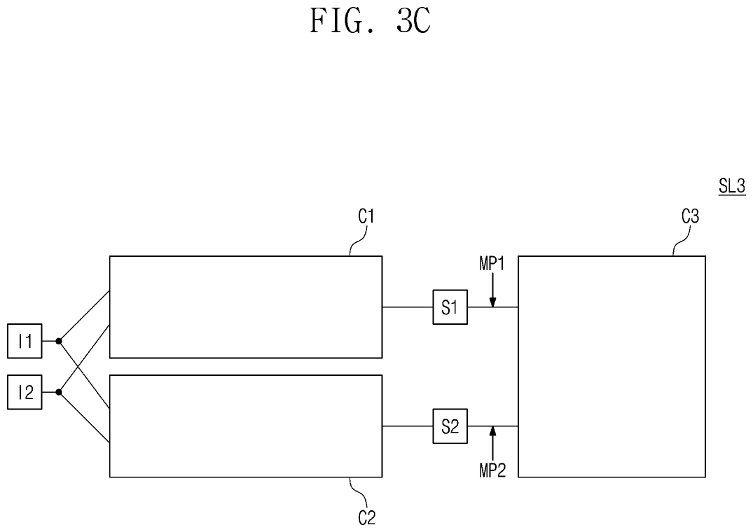

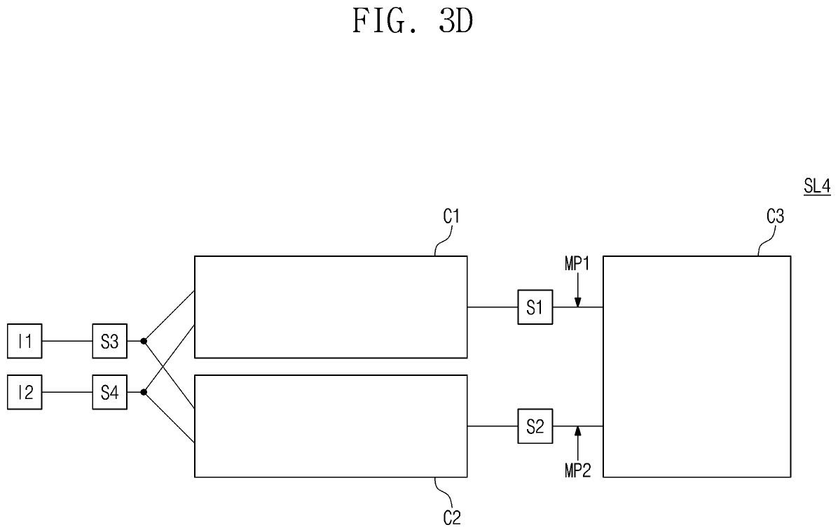

By way of example only and without limitation or loss of generality, FIGS. 3A to 3D are diagrams conceptually illustrating examples of a source layout, according to some embodiments. Referring to FIG. 3A, a first source layout SL1 may include a first circuit C1, a second circuit C2, and a third circuit C3. The first circuit C1 may receive signals from a first input node I1 and a second input node I2. The second circuit C2 may receive signals from the first input node I1 and the second input node I2. In an embodiment, the first input node I1 and the second input node I2 may be input pads. Accordingly, any other circuit may not exist in front of the first input node I1 and the second input node I2.

The first circuit C1 may perform various operations based on the signal of the first input node I1 and the signal of the second input node I2. For example, the first circuit C1 may include combinational logic. The second circuit C2 may perform various operations based on the signal of the first input node I1 and the signal of the second input node I2. For example, the second circuit C2 may include combinational logic.

The third circuit C3 may receive an output signal of the first circuit C1 and an output signal of the second circuit C2. The third circuit C3 may perform various operations based on the output signal of the first circuit C1 and the output signal of the second circuit C2.

In an embodiment, for the structural test of the first circuit C1, the layout generation module 101 (FIG. 1) may set a first measure point MP1 between an output of the first circuit C1 and a first input of the third circuit C3. For the structural test of the second circuit C2, the layout generation module 101 (FIG. 1) may set a second measure point MP2 between an output of the second circuit C2 and a second input of the third circuit C3.

Referring to FIG. 3B, the first circuit C1 and the second circuit C2 of a second source layout SL2 may include storage elements “S”, compared to FIG. 3A. Each of the storage elements “S” may include at least one of various storage elements such as, for example, a flip-flop and a latch.

Referring to FIG. 3C, a third source layout SL3 may further include a first storage element S1 between the first circuit C1 and the first measure point MP1, and may further include a second storage element S2 between the second circuit C2 and the second measure point MP2, compared to FIG. 3A. That is, the first storage element S1 may be coupled between the output of the first circuit C1 and the first input of the third circuit C3, and the second storage element S2 may be coupled between the output of the second circuit C2 and the second input of the third circuit C3.

Referring to FIG. 3D, a fourth source layout SL4 may further include a third storage element S3 between the first input node I1 and the first and second circuits C1 and C2, respectively, and may further include a fourth storage element S4 between the second input node I2 and the first and second circuits C1 and C2, compared to FIG. 3C.

In an embodiment, the storage element described with reference to FIGS. 3A to 3D may be configured to temporarily store a signal value for the purpose of setting a time period of a clock signal. The storage element may store an input signal in a first clock cycle of the clock signal and may output the stored input signal in a second clock cycle of the clock signal. That is, one clock cycle may be required for the storage element to output an input signal. An element that is not a storage element may not require one clock cycle to output an input signal.

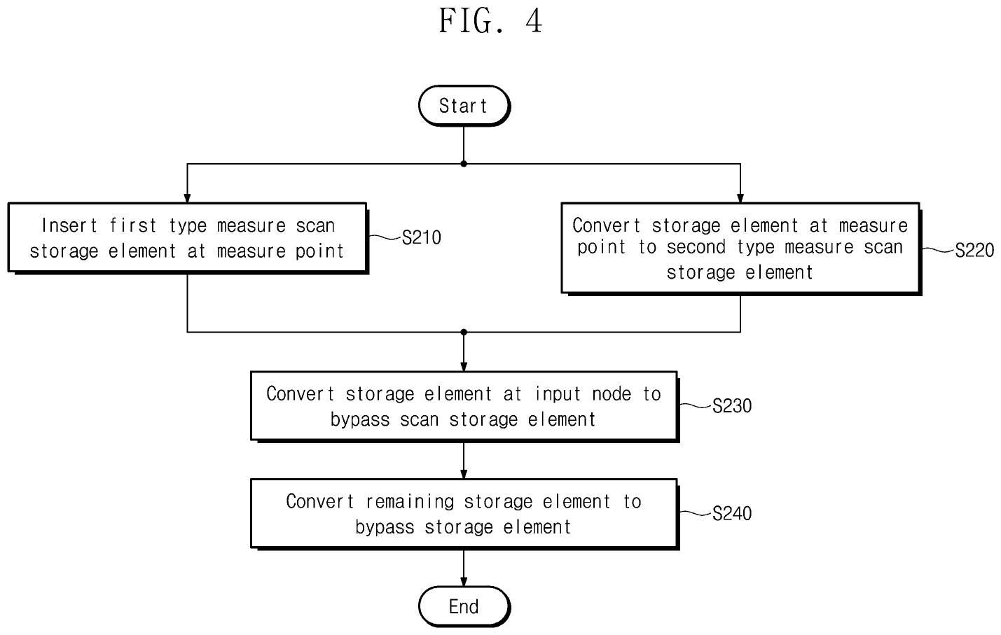

FIG. 4 is a diagram illustrating at least a portion of an example method in which the electronic device 100 (FIG. 1) generates a DFT layout from a source layout. Referring to FIGS. 1 and 4, in operation S210, the electronic device 100 may insert a first type measure scan storage element at a measure point. For example, when a storage element does not exist just in front of the first measure point MP1 or the second measure point MP2 of the example source layout SL1, SL2, SL3, or SL4 shown in FIGS. 3A to 3D, the DFT layout generator 102 of the layout generation module 101 driven by the electronic device 100 may insert the first type measure scan storage element(s) at the first measure point MP1 or the second measure point MP2.

The first type measure scan storage element may include a first input, a second input, a first output, and a second output. In a first operation mode (e.g., a specified function mode of performing a specified function), the first type measure scan storage element may store the signal of the first input (i.e., a specified function input) and may transfer the signal of the first input to the first output (i.e., a specified function output).

In a second operation mode (e.g., a test mode), the first type measure scan storage element may store the signal of the second input (i.e., a test input), may store the signal of the first input after transferring the signal of the second input to the second output (i.e., a test output), and may transfer the signal of the first input to the second output. For example, the first type measure scan storage element may transfer the signal of the second input to the second output, and may transfer the signal of the first input to the second output after a given time passes.

The first type measure scan storage element may perform the specified function by transferring the signal of the first input to the first output, may output an initial value of the structural test by transferring the signal of the second input to the second output, and may output a result of the structural test by transferring the signal of the first input to the second output.

In operation S220, the electronic device 100 may convert the storage element at the measure point to a second type measure scan storage element. For example, when a storage element exists just in front of the first measure point MP1 or the second measure point MP2 of the source layout SL1, SL2, SL3, or SL4 shown in FIGS. 3A to 3D, the DFT layout generator 102 of the layout generation module 101 driven by the electronic device 100 may convert a storage element(s) just in front of the first measure point MP1 or the second measure point MP2 to the second type measure scan storage element(s).

The second type measure scan storage element may include a first input, a second input, a first output, and a second output. In the first operation mode (e.g., a specified function mode of performing a specified function), the second type measure scan storage element may store the signal of the first input (i.e., a specified function input) and may transfer the signal of the first input to the first output (i.e., a specified function output).

In the second operation mode (e.g., a test mode), the second type measure scan storage element may store the signal of the second input (i.e., a test input), may store the signal of the first input after transferring the signal of the second input to the second output (i.e., a test output), and may transfer the signal of the first input to the second output. For example, the second type measure scan storage element may transfer the signal of the second input to the second output, and may transfer the signal of the first input to the second output after a given time passes.

The second type measure scan storage element may perform the specified function by transferring the signal of the first input to the first output, may output an initial value of the structural test by transferring the signal of the second input to the second output, and may output a result of the structural test by transferring the signal of the first input to the second output.

In an embodiment, operation S210 and operation S220 may be selectively performed. When a storage element does not exist just in front of the measure point MP1 or MP2, operation S210 may be performed; when a storage element exists just in front of the measure point MP1 or MP2, operation S220 may be performed.

In an embodiment, the first type measure scan storage element and the second type measure scan storage element may have the same structure and may perform the same function. The first type measure scan storage element and the second type measure scan storage element may distinguish whether a constituent element is an inserted constituent element or a converted constituent element.

In operation S230, the electronic device 100 may convert a storage element of an input node to a bypass scan storage element. For example, when a storage element exists just at the back of the input node I1 or I2, the DFT layout generator 102 of the layout generation module 101 driven by the electronic device 100 may convert a storage element just at the back of the input node I1 or I2 of the source layout (e.g., SL1, SL2, SL3, or SL4 shown in FIGS. 3A to 3D) to the bypass scan storage element into the bypass scan storage element.

The bypass scan storage element may include a first input, a second input, a first output, and a second output. In the first operation mode (e.g., a specified function mode), the bypass scan storage element may store the signal of the first input and may transfer the stored signal of the first input to the first output.

In a first sub-mode (e.g., a first test mode) of the second operation mode (e.g., a test mode), the bypass scan storage element may bypass the signal of the first input to the second output; in a second sub-mode (e.g., a second test mode) of the second operation mode (e.g., a test mode), the bypass scan storage element may store the signal of the second input and may transfer the signal of the second input to the second output.

The bypass scan storage element may perform the specified function by transferring the signal of the first input to the first output, may support to a result of a first structural test (e.g., a stuck-at fault test) by bypassing the signal of the second input to the second output (or by providing no bypass scan storage element when a storage element does not exist at an input node), and may support to generate a result of a second structural test (e.g., a defect test of a transmission delay) by storing the signal of the second input and transferring the stored signal to the second output (or by providing no bypass scan storage element when a storage element does not exist at an input node).

When a storage element does not exist just at the back of the input node I1 or I2, the DFT layout generator 102 of the layout generation module 101 driven by the electronic device 100 may omit operation S230.

In operation S240, the electronic device 100 may convert the remaining storage element(s) into a bypass storage element. For example, the DFT layout generator 102 of the layout generation module 101 driven by the electronic device 100 may convert a storage element between a storage element just in front of the measure point MP1 or MP2 of the source layout SL1, SL2, SL3, or SL4 (if a storage element does not exist, the measure point MP1 or MP2) and a storage element just at the back of the input node I1 or I2 (if a storage element does not exist, the input node I1 or I2), to the bypass storage element.

In the first operation mode (e.g., a specified function mode), the bypass storage element may store the input signal and may transfer the input signal to an output. In the first operation mode, the bypass storage element may consume one clock cycle. In the second operation mode (e.g., a test mode), the bypass storage element may bypass (i.e., transmit) the input signal to the output.

The DFT layout generator 102 may generate the DFT layout from the source layout based on the above examples. However, the rules that are used for the DFT layout generator 102 to generate the DFT layout from the source layout are not limited.

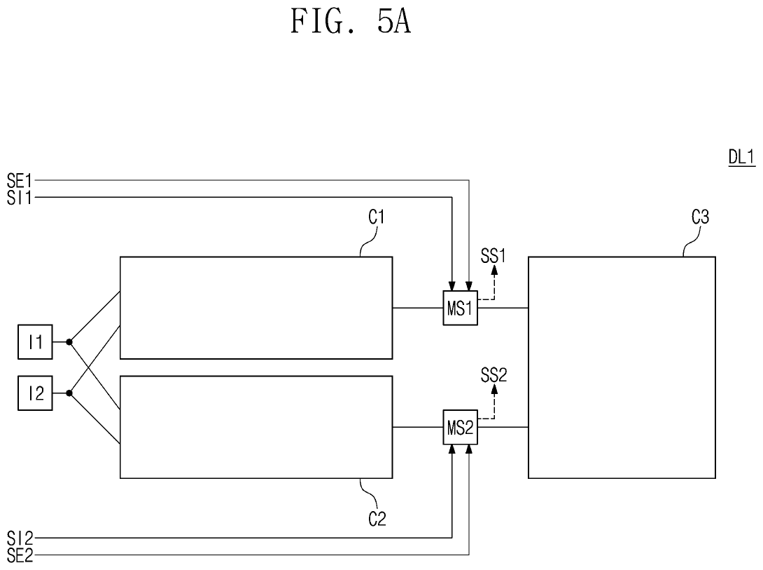

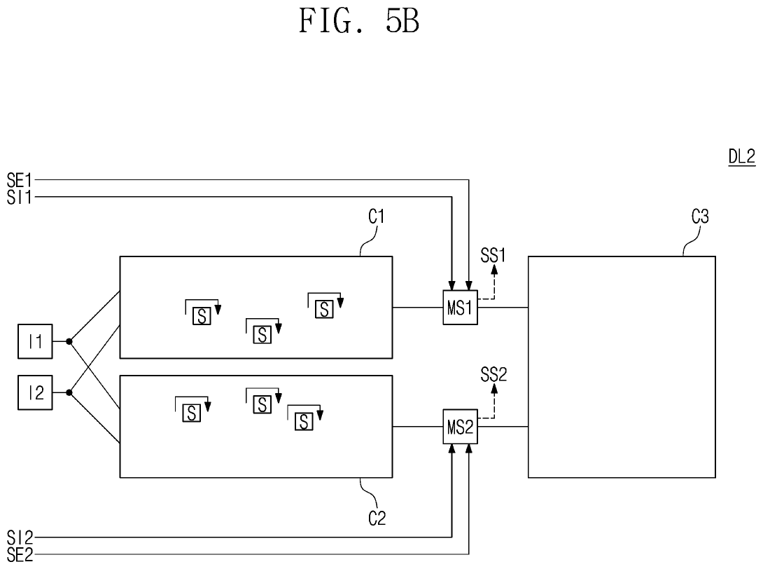

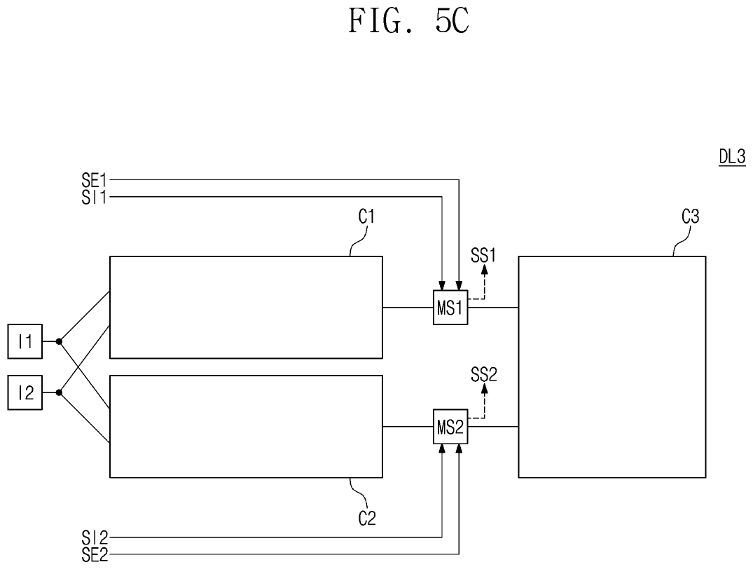

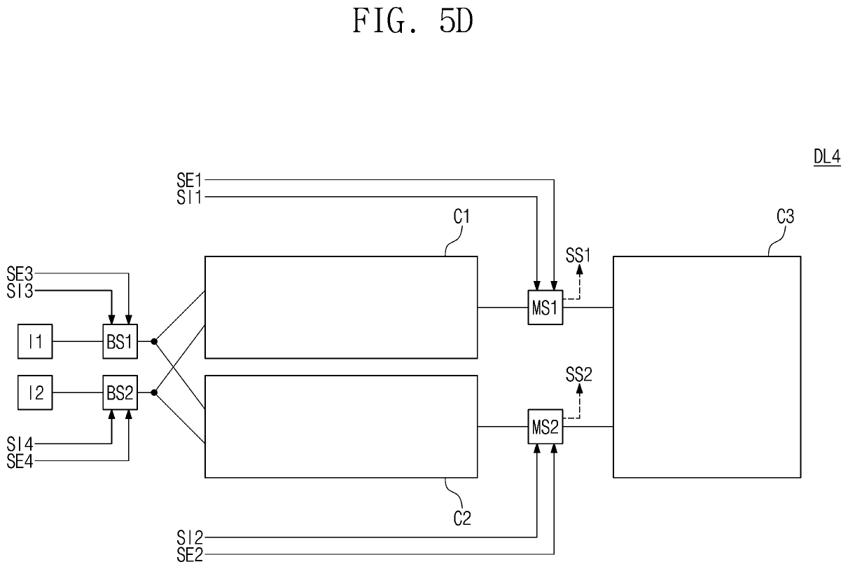

FIGS. 5A to 5D are diagrams illustrating examples of DFT layouts DL1, DL2, DL3 and DL4, respectively, generated from FIGS. 3A to 3D, according to embodiments. Referring to FIGS. 3A, 4, and 5A, the electronic device 100 (FIG. 1) may add a first measure scan storage element MS1 at the first measure point MP1 (refer to operation S210). Also, the electronic device 100 (FIG. 1) may add a second measure scan storage element MS2 at the second measure point MP2 (refer to operation S210).

The first measure scan storage element MS1 may include a first input receiving a signal from the first circuit C1, a second input receiving a signal from a first scan input SI1, a first output outputting a signal to the third circuit C3, and a second output outputting a first measure signal SS1.

In the first operation mode (e.g., a specified function mode), the first measure scan storage element MS1 may transfer the output of the first circuit C1 to the third circuit C3. In the second operation mode (e.g., a test mode), the first measure scan storage element MS1 may output the signal of the first scan input SI1 as the first measure signal SS1 and may then output the output signal of the first circuit C1 as the first measure signal SS1. In an embodiment, the first measure scan storage element MS1 may output the signal of the first scan input SI1 when a signal of a first scan enable input SE1 is activated, and may output the signal of the first circuit C1 when the signal of the first scan enable input SE1 is deactivated. It may be assumed that the signal of the first scan enable input SE1 and the signal of the first scan input SI1 are received from an external device through pads.

The second measure scan storage element MS2 may include a first input receiving a signal from the second circuit C2, a second input receiving a signal from a second scan input SI2, a first output outputting a signal to the third circuit C3, and a second output outputting a second measure signal SS2.

In the first operation mode (e.g., a specified function mode), the second measure scan storage element MS2 may transfer the output of the second circuit C2 to the third circuit C3. In the second operation mode (e.g., a test mode), the second measure scan storage element MS2 may output the signal of the second scan input SI2 as the second measure signal SS2 and may then output the output signal of the second circuit C2 as the second measure signal SS2. In an embodiment, the second measure scan storage element MS2 may output the signal of the second scan input SI2 when a signal of a second scan enable input SE2 is activated and may output the signal of the second circuit C2 when the signal of the second scan enable input SE2 is deactivated. It may be assumed that the signal of the second scan enable input SE2 and the signal of the second scan input SI2 are received from the external device through pads.

Referring to FIGS. 3B and 5B, as described with reference to operation S240 of FIG. 4, the electronic device 100 may convert the storage elements “S” of the first circuit C1 and the second circuit C2 of the second source layout SL2 to the bypass storage elements, compared to FIG. 5A. In an embodiment, the bypass storage elements are shown by the storage elements “S” including arrows including bypass paths.

In the first operation mode (e.g., a specified function mode), the bypass storage elements may store the input signal and may transfer the input signal to the output. In the second operation mode (e.g., a test mode), the bypass storage elements may bypass the input signal to the output.

Referring to FIGS. 3C and 5C, as described with reference to operation S220 of FIG. 4, the electronic device 100 may convert the first storage element S1 between the first circuit C1 and the first measure point MP1 of the third source layout SL3 to the first measure scan storage element MS1 and may convert the second storage element S2 between the second circuit C2 and the second measure point MP2 of the third source layout SL3 to the second measure scan storage element MS2, compared to FIG. 5A.

The first measure scan storage element MS1 may include a first input receiving a signal from the first circuit C1, a second input receiving a signal from the first scan input SI1, a first output outputting a signal to the third circuit C3, and a second output outputting the first measure signal SS1.

In the first operation mode (e.g., a specified function mode), the first measure scan storage element MS1 may store the output of the first circuit C1 and may transfer the stored signal to the third circuit C3. In the second operation mode (e.g., a test mode), after the first measure scan storage element MS1 may store the signal of the first scan input SI1 and may output the stored signal as the first measure signal SS1, the first measure scan storage element MS1 may store the output signal of the first circuit C1 and may output the stored signal as the first measure signal SS1. In an embodiment, the first measure scan storage element MS1 may store and output the signal of the first scan input SI1 when the signal of the first scan enable input SE1 is activated and may store and output the signal of the first circuit C1 when the signal of the first scan enable input SE1 is deactivated. It may be assumed that the signal of the first scan enable input SE1 and the signal of the first scan input SI1 are received from the external device through the pads.

The second measure scan storage element MS2 may include a first input receiving a signal from the second circuit C2, a second input receiving a signal from the second scan input SI2, a first output outputting a signal to the third circuit C3, and a second output outputting the second measure signal SS2.

In the first operation mode (e.g., a specified function mode), the second measure scan storage element MS2 may store the output of the second circuit C2 and may transfer the stored signal to the third circuit C3. In the second operation mode (e.g., a test mode), after the second measure scan storage element MS2 stores the signal of the second scan input SI2 and outputs the stored signal as the second measure signal SS2, the second measure scan storage element MS2 may store the output signal of the second circuit C2 and may output the stored signal as the second measure signal SS2. In an embodiment, the second measure scan storage element MS2 may store and output the signal of the second scan input SI2 when the signal of the second scan enable input SE2 is activated and may store and output the signal of the second circuit C2 when the signal of the second scan enable input SE2 is deactivated. It may be assumed that the signal of the second scan enable input SE2 and the signal of the second scan input SI2 are received from the external device through the pads.

Referring to FIGS. 3D and 5D, as described with reference to operation S230 of FIG. 4, the electronic device 100 may convert the third storage element S3 between the first input node I1 and the first and second circuits C1 and C2 of the fourth source layout SL4 to a first bypass scan storage element BS1, and may convert the fourth storage element S4 between the second input node I2 and the first and second circuits C1 and C2 of the fourth source layout SL4 to a second bypass scan storage element BS2, compared to FIG. 5C.

The first bypass scan storage element BS1 may include a first input receiving a signal from the first input node I1, a second input receiving a signal from the third scan input S13, and an output outputting a signal to the first circuit C1 and the second circuit C2.

In the first operation mode (e.g., a specified function mode), the first bypass scan storage element BS1 may store the signal of the first input node I1 and may transfer the stored signal to the first circuit C1 and the second circuit C2. In the first sub-mode (e.g., a first test mode) of the second operation mode (e.g., a test mode), the first bypass scan storage element BS1 may bypass the signal of the first input node I1 to the first circuit C1 and the second circuit C2.

In the second sub-mode (e.g., a second test mode) of the second operation mode (e.g., a test mode), the first bypass scan storage element BS1 may store the signal of the third scan input SI3 and may output the stored signal to the first circuit C1 and the second circuit C2. In an embodiment, the first bypass scan storage element BS1 may store and output the signal of the third scan input SI3 when the signal of the third scan enable input SE3, supplied to the first bypass scan storage element BS1, is activated and may store and output the signal of the first input node I1 when the signal of the third scan enable input SE3 is deactivated. It may be assumed that the signal of the third scan enable input SE3 and the signal of the third scan input SI3 are received from the external device through the pads.

The second bypass scan storage element BS2 may include a first input receiving a signal from the second input node I2, a second input receiving a signal from the fourth scan input SI4, and an output outputting a signal to the first circuit C1 and the second circuit C2.

In the first operation mode (e.g., a specified function mode), the second bypass scan storage element BS2 may store the signal of the second input node I2 and may transfer the stored signal to the first circuit C1 and the second circuit C2. In the first sub-mode (e.g., a first test mode) of the second operation mode (e.g., a test mode), the second bypass scan storage element BS2 may bypass the signal of the second input node I2 to the first circuit C1 and the second circuit C2.

In the second sub-mode (e.g., a second test mode) of the second operation mode (e.g., a test mode), the second bypass scan storage element BS2 may store the signal of the fourth scan input SI4 and may output the stored signal to the first circuit C1 and the second circuit C2. In an embodiment, the second bypass scan storage element BS2 may store and output the signal of the fourth scan input SI4 when the signal of the fourth scan enable input SE4, supplied to the second bypass scan storage element BS2, is activated and may store and output the signal of the second input node I2 when the signal of the fourth scan enable input SE4 is deactivated. It may be assumed that the signal of the fourth scan enable input SE4 and the signal of the second scan input SI2 are received from the external device through the pads.

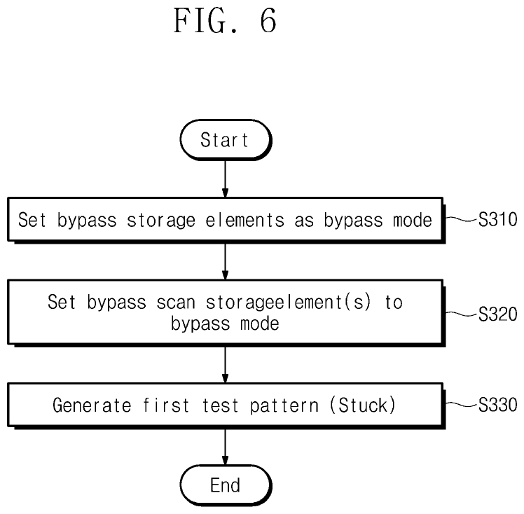

FIG. 6 is a diagram illustrating at least a portion of an example method in which the electronic device 100 generates a first test pattern, according to one or more embodiments. Referring to FIGS. 1 and 6, in operation S310, the layout generation module 101 driven by the electronic device 100 may set the bypass storage elements of the DFT layout DL1, DL2, DL3, or DL4 to a bypass mode. The bypass mode, for example, the bypass mode of the bypass storage elements, may correspond to the second operation mode (e.g., a test mode).

In operation S320, the layout generation module 101 may set the bypass scan storage element(s) of the DFT layout DL1, DL2, DL3, or DL4 to the bypass mode. The bypass mode of the bypass scan storage elements may correspond, for example, to the first sub-mode (or a first test mode) of the second operation mode (e.g., a test mode).

In operation S330, the EDA tool 103 of the layout generation module 101 may generate a first test pattern(s) based on the set DFT layout DL1, DL2, DL3, or DL4. According to the settings in operation S310 and operation S320, a signal input to the first input node I1 or the second input node I2 bypasses the storage elements so as to be transferred to the measure scan storage element MS1 or MS2. The first test pattern may be used to detect a stuck-at fault or defect of the DFT layout DL1, DL2, DL3, or DL4, for example.

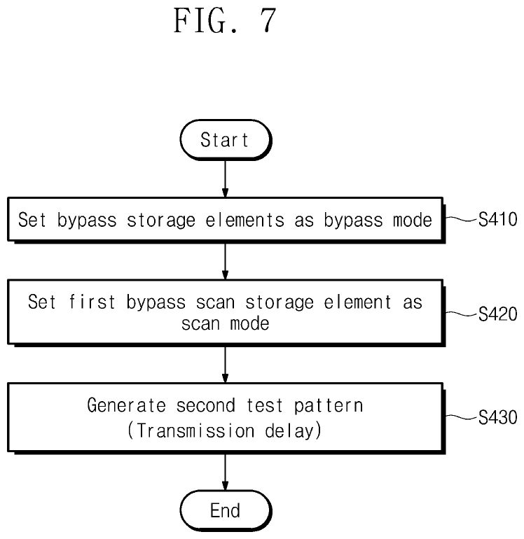

FIG. 7 is a diagram illustrating at least a portion of an example method in which the electronic device 100 generates a second test pattern, according to one or more embodiments. Referring to FIGS. 1 and 7, in operation S410, the layout generation module 101 driven by the electronic device 100 may set the bypass storage elements of the DFT layout DL1, DL2, DL3, or DL4 to the bypass mode. The bypass mode, for example, the bypass mode of the bypass storage elements, may correspond to the second operation mode (e.g., a test mode).

In operation S420, the layout generation module 101 may set the bypass scan storage elements of the DFT layout DL1, DL2, DL3, or DL4 to a scan mode. The scan mode of the bypass scan storage elements may correspond, for example, to the second sub-mode (or a second test mode) of the second operation mode (e.g., a test mode).

In operation S430, the EDA tool 103 of the layout generation module 101 may generate a second test pattern(s) based on the set DFT layout DL1, DL2, DL3, or DL4. According to the settings in operation S410 and operation S420, a signal input to the first input node I1 or the second input node I2 is stored by the bypass scan storage element BS1 or BS2 and is transferred to the first circuit C1 and the second circuit C2 at the given timing. The signal transferred to the first circuit C1 and the second circuit C2 may arrive at the measure scan storage element MS1 or MS2 after a transmission delay time determined by the design of the first circuit C1 and the second circuit C2. As the signal stored by the measure scan storage element MS1 or MS2 is measured after the given transmission delay time, the second test pattern may be used to detect a transmission delay defect of the DFT layout DL1, DL2, DL3, or DL4.

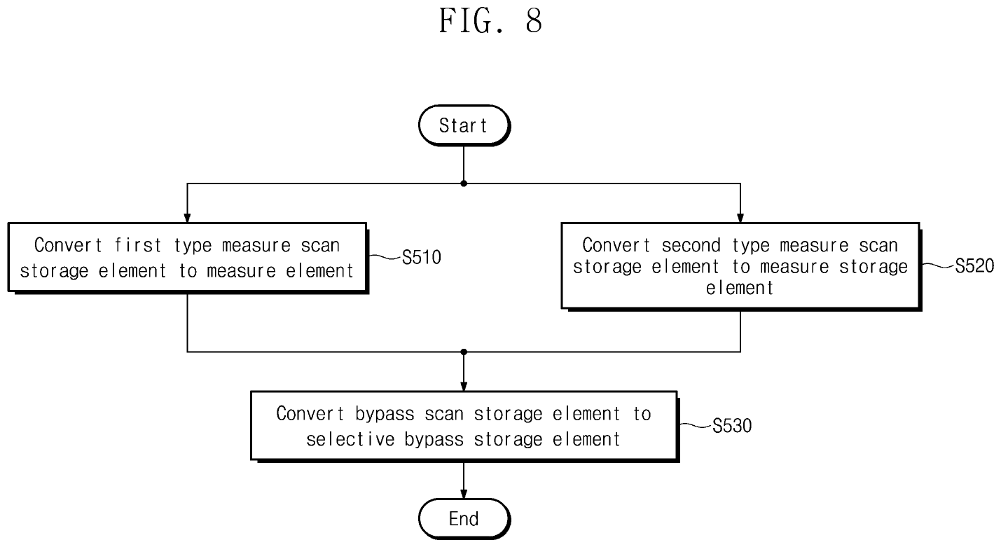

FIG. 8 is a diagram illustrating at least a portion of an example method in which the electronic device 100 generates a hybrid layout from a DFT layout, according to one or more embodiments. Referring to FIGS. 1 and 8, in operation S510, the electronic device 100 may convert a first type measure scan storage element of a DFT layout to a measure element. For example, as described with reference to operation S210 of FIG. 4, when a storage element does not exist just in front of the first measure point MP1 or the second measure point MP2 of the source layout SL1, SL2, SL3, or SL4, the first type measure scan storage element(s) may be inserted at the first measure point MP1 or the second measure point MP2. The hybrid layout generator 104 of the layout generation module 101 may convert the first type measure scan storage element of the source layout SL1, SL2, SL3, or SL4 to a measure element.

The measure element may include an input, a first output, and a second output. The measure element may transfer a signal of the input to the first output (i.e., a specified function output) in the first operation mode (e.g., a specified function mode of performing a specified function).

The measure element may transfer the signal of the input to the second output (i.e., a test output) in the second operation mode (e.g., a test mode).

In operation S520, the electronic device 100 may convert a second type measure scan storage element to a measure storage element. For example, as described with reference to operation S220 of FIG. 4, when a storage element exists just in front of the first measure point MP1 or the second measure point MP2 of the source layout SL1, SL2, SL3, or SL4, a storage element(s) just in front of the first measure point MP1 or the second measure point MP2 is converted to the second type measure scan storage element(s). The hybrid layout generator 104 of the layout generation module 101 may convert second type measure scan storage element of the source layout SL1, SL2, SL3, or SL4 to a measure storage element.

The measure storage element may include an input, a first output, and a second output. In the first operation mode (e.g., a specified function mode of performing a specified function), the measure storage element may store a signal of the input and may transfer the signal of the input to the first output (i.e., a specified function output).

In the second operation mode (e.g., a test mode), the measure storage element may store the signal of the input and may transfer the signal of the input to the second output (i.e., a test output).

In an embodiment, operation S510 and operation S520 may be performed selectively (e.g., sequentially) or in parallel (i.e., concurrently). When the first type measure scan storage element exists, operation S510 may be performed; when the second type measure scan storage element exists, operation S520 may be performed.

In operation S530, the electronic device 100 may convert the bypass scan storage element to a selective bypass storage element. In the first operation mode (e.g., a specified function mode), the selective bypass storage element may store the input signal and may transfer the input signal to the output. In the first operation mode, the selective bypass storage element may consume one clock cycle. The selective bypass storage element may bypass the input signal to the output in the first sub-mode (e.g., a first test mode) of the second operation mode (e.g., a test mode). In the second sub-mode (e.g., a second test mode) of the second operation mode (e.g., a test mode), the selective bypass storage element may store the input signal and may transfer the input signal to the output. When the bypass scan storage element does not exist, operation S530 may be omitted.

The hybrid layout generator 104 may generate the hybrid layout from the DFT layout based on the above examples. However, the rules that are used for the hybrid layout generator 104 to generate the hybrid layout from the DFT layout are not limited.

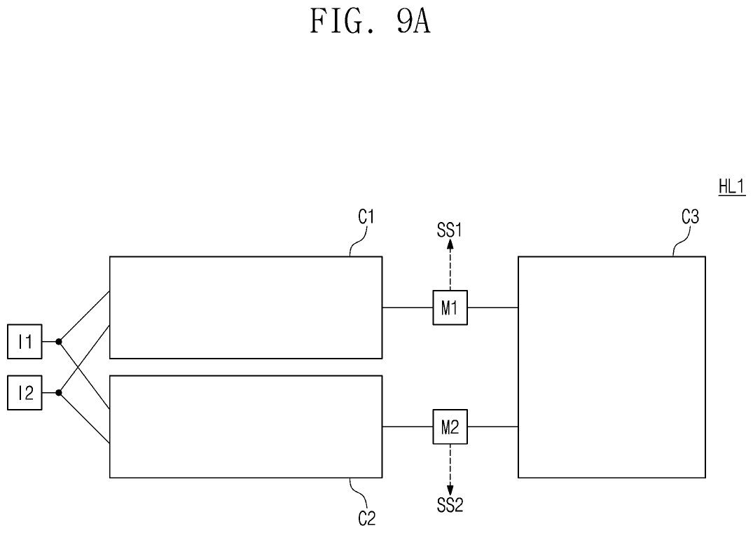

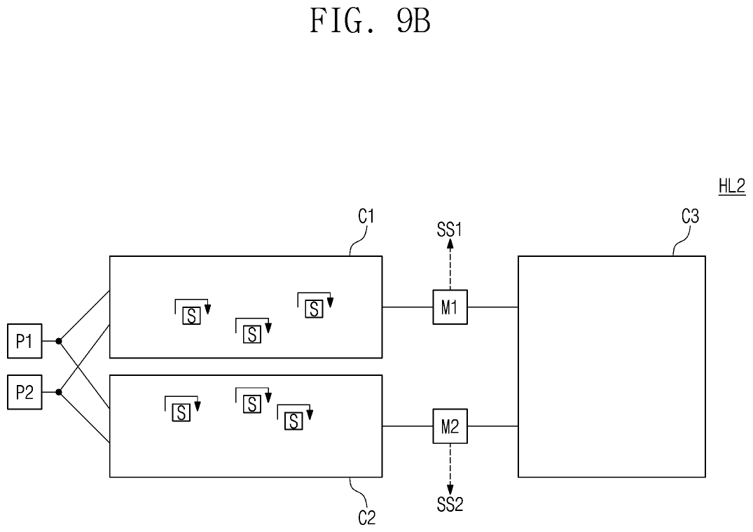

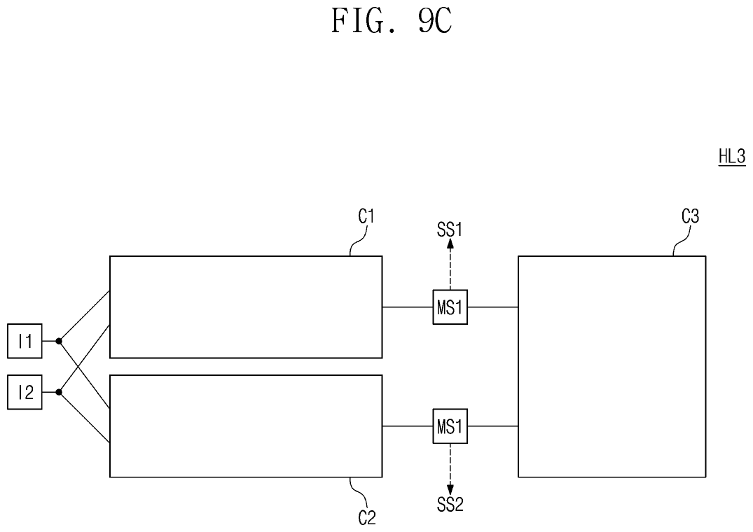

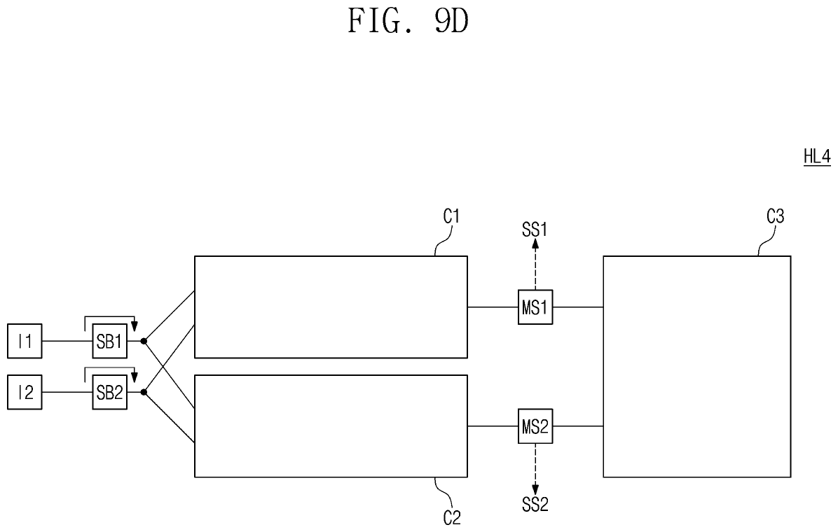

FIGS. 9A to 9D are diagrams illustrating examples of hybrid layouts HL1, HL2, HL3 and HL4, generated from FIGS. 5A to 5D, respectively, according to one or more embodiments. Referring to FIGS. 3A, 5A, and 9A, a first hybrid layout HL1 may be identical to the first source layout SL1 except that a first measure element M1 is added at the first measure point MP1 and a second measure element M2 is added at the second measure point MP2. Storage elements and wires associated with the scan chain are not added.

Referring to FIGS. 3B, 5B, and 9B, a second hybrid layout HL2 may be identical to the second source layout SL2 except that the first measure element M1 is added at the first measure point MP1, the second measure element M2 is added at the second measure point MP2, and storage elements “S” of the first circuit C1 and the storage elements “S” of the second circuit C2 are converted to bypass storage elements. Storage elements and wires associated with the scan chain are not added.

Referring to FIGS. 3C, 5C, and 9C, a third hybrid layout HL3 may be identical to the third source layout SL3 except that the first storage element S1 is converted to the first measure scan storage element MS1 and the second storage element S2 is converted to the second measure scan storage element MS2. Storage elements and wires associated with the scan chain are not added.

Referring to FIGS. 3D, 5D, and 9D, a fourth hybrid layout HL4 may be identical to the fourth source layout SL4 except that the first storage element S1 is converted to the first measure scan storage element MS1, the second storage element S2 is converted to the second measure scan storage element MS2, the third storage element S3 is converted to a first selective bypass storage element SB1, and the fourth storage element S4 is converted to a second selective bypass storage element SB2. Storage elements and wires associated with the scan chain are not added.

As described with reference to FIGS. 9A to 9D, the hybrid layout HL1, HL2, HL3, or HL4 does not include constituent elements and wires associated with the scan chain. An electronic device manufactured based on the hybrid layout HL1, HL2, HL3, or HL4 may be tested in structure (i.e., in situ) by using the first test pattern and the second test pattern generated in the process of generating the hybrid layout HL1, HL2, HL3, or HL4, without an overhead of the scan chain.

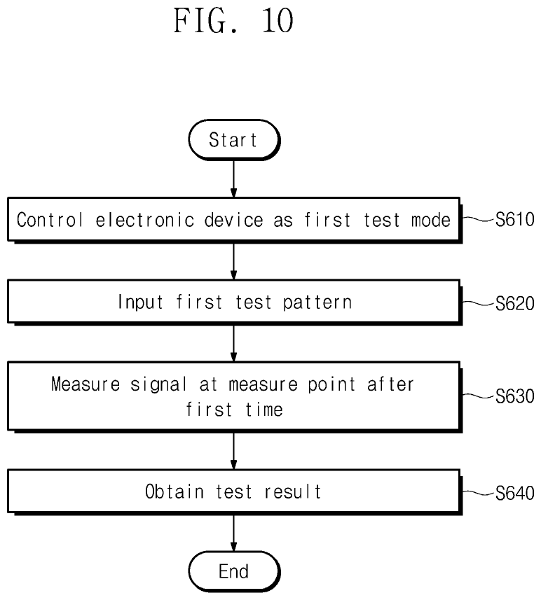

FIG. 10 is a diagram illustrating at least a portion of a first example method of testing an electronic device manufactured based on the hybrid layout HL1, HL2, HL3, or HL4 shown in FIGS. 9A to 9D, according to one or more embodiments. For example, a structure of an electronic device manufactured based on the hybrid layout HL1, HL2, HL3, or HL4 may correspond to the hybrid layout HL1, HL2, HL3, or HL4. The electronic device manufactured based on the hybrid layout HL1, HL2, HL3, or HL4 may be tested by the advanced test equipment (ATE) (not explicitly illustrated, but implied).

Referring to FIGS. 9A to 9D and 10, in operation S610, the ATE may control the electronic device manufactured (i.e., device under test (DUT)) based on the hybrid layout HL1, HL2, HL3, or HL4 so as to operate in a first test mode. As the electronic device manufactured based on the hybrid layout HL1, HL2, HL3, or HL4 is controlled to operate in the first test mode, the bypass storage element of the electronic device manufactured based on the hybrid layout HL1, HL2, HL3, or HL4 may enter the bypass mode, the selective bypass storage element thereof may enter the bypass mode, the measure element thereof may enter the measure mode, and the measure storage element thereof may enter the measure mode.

In operation S620, the ATE may input the first test pattern to the first input node I1 and the second input node I2 of the electronic device manufactured based on the hybrid layout HL1, HL2, HL3, or HL4. The bypass storage element of the bypass mode may bypass the input signal to the output. The selective bypass storage element of the bypass mode may bypass the input signal to the output. The measure element of the measure mode may transfer the input signal as the measure signal. The measure storage element of the measure mode may store the input signal and may transfer the stored signal as the measure signal.

In operation S630, the ATE may measure the signal at the measure element after a first time. The first time may be determined by a time on a design, which is taken for the first test pattern input to the first input node I1 and the second input node I2 to arrive at the measure element ME1 or ME2 or the measure storage element MS1 or MS2, in the electronic device manufactured based on the hybrid layout HL1, HL2, HL3, or HL4. For example, the ATE may measure the signal at a node (or a pad) where the electronic device manufactured based on the hybrid layout HL1, HL2, HL3, or HL4 outputs the measure signal.

In operation S640, the ATE may obtain a test result. For example, the ATE may determine whether a stuck-at fault or other defect exists at the first circuit C1 or the second circuit C2, based on a level of the measured signal. The electronic device having the stuck defect may be discarded as a defective product.

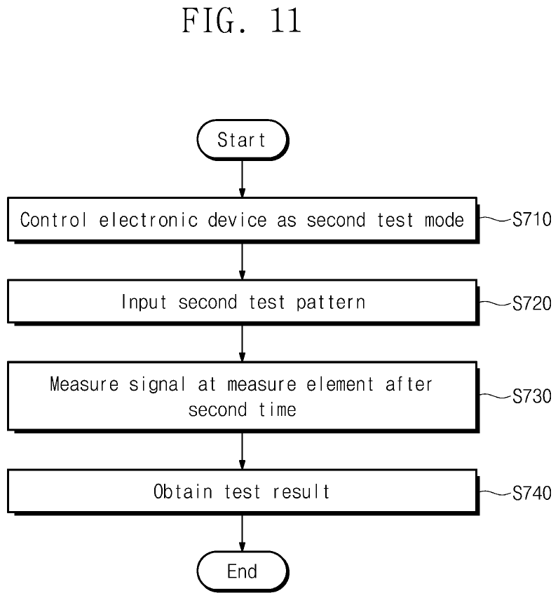

FIG. 11 is a diagram illustrating at least a portion of a second example method of testing an electronic device manufactured based on the hybrid layout HL1, HL2, HL3, or HL4 shown in FIGS. 9A-9D, respectively, according to one or more embodiments. Referring to FIGS. 9A to 9D and 11, in operation S710, the ATE may control the electronic device manufactured based on the hybrid layout HL1, HL2, HL3, or HL4 so as to operate in a second test mode. As the electronic device manufactured based on the hybrid layout HL1, HL2, HL3, or HL4 is controlled to operate in the second test mode, the bypass storage element of the electronic device manufactured based on the hybrid layout HL1, HL2, HL3, or HL4 may enter the bypass mode, the selective bypass storage element thereof may enter the specified function mode, the measure element thereof may enter the measure mode, and the measure storage element thereof may enter the measure mode.

In operation S720, the ATE may input the second test pattern to the first input node I1 and the second input node I2 of the electronic device manufactured based on the hybrid layout HL1, HL2, HL3, or HL4. The bypass storage element of the bypass mode may bypass the input signal to the output. The selective bypass storage element of the specified function mode may store the input signal and may transfer the stored input signal to the output. The measure element of the measure mode may transfer the input signal as the measure signal. The measure storage element of the measure mode may store the input signal and may transfer the stored signal as the measure signal.

In operation S730, the ATE may measure the signal at the measure element after a second time. The first time may be determined by a time on a design, which is taken for the second test pattern input to the first input node I1 and the second input node I2 to arrive at the measure element ME1 or ME2 or the measure storage element MS1 or MS2, in the electronic device manufactured based on the hybrid layout HL1, HL2, HL3, or HL4. For example, the ATE may measure the signal at a node (or a pad) where the electronic device manufactured based on the hybrid layout HL1, HL2, HL3, or HL4 outputs the measure signal.

In operation S740, the ATE may obtain a test result. For example, the ATE may determine whether a transmission delay defect exists at the first circuit C1 or the second circuit C2, based on a level of the measured signal. The electronic device having the transmission delay defect may be discarded as a defective product.

In an embodiment, the test may be performed at a wafer level. Electronic devices manufactured based on the hybrid layout HL1, HL2, HL3, or HL4 may be simultaneously tested.

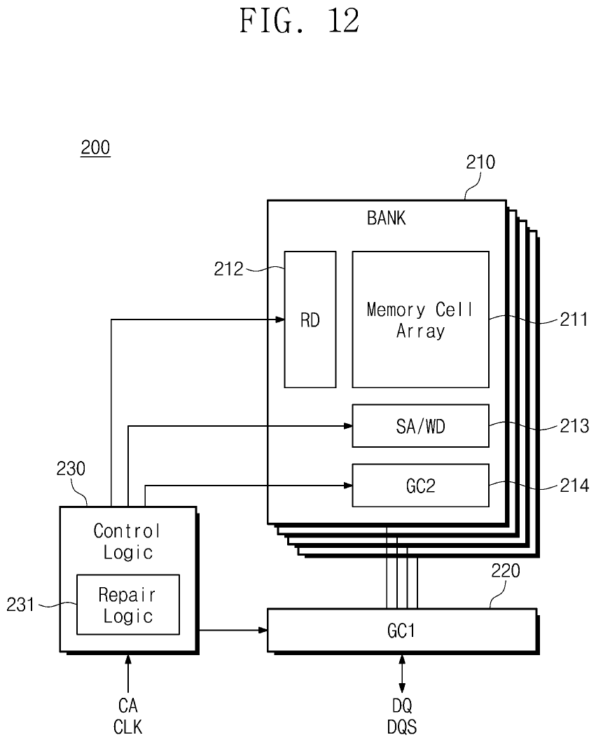

FIG. 12 is a diagram illustrating an example electronic device manufactured based on the hybrid layout HL1, HL2, HL3, or HL4. Referring to FIG. 12, an electronic device 200 may include a dynamic random access memory. The electronic device 200 may include a plurality of banks (BANK) 210, a first gating circuit (GC1) 220, and control logic 230.

Each of the plurality of banks 210 may include a memory cell array 211, a row decoder (RD) 212, a sense amplifier and write driver (SA/WD) 213, and a second gating circuit (GC2) 214.

The memory cell array 211 may include memory cells arranged in rows and columns, although embodiments of the inventive concept are not limited to such an arrangement of the memory cells. The rows of the memory cells may be connected to word lines, and the columns of the memory cells may be connected to bit lines.

The row decoder 212 may be connected with the rows of the memory cells in the memory cell array 211 through the word lines. The row decoder 212 may activate one (e.g., a word line) of the rows of the memory cells in the memory cell array 211 under control of the control logic 230, for example, in response to a row address received from the control logic 230.

The sense amplifier and write driver 213 may be connected with the columns of the memory cells in the memory cell array 211 through the bit lines. When a row of the memory cell array 211 is selected and activated, the sense amplifier and write driver 213 may read data stored in memory cells of the activated row under control of the control logic 230. When the selected row of the memory cell array 211 is deactivated, the sense amplifier and write driver 213 may write data in the memory cells of the row to be deactivated under control of the control logic 230. The sense amplifier and write driver 213 may include a plurality of sense amplifiers and a plurality of write drivers, each of which corresponds to each bit line.

The second gating circuit 214 may be connected with the plurality of sense amplifiers and the plurality of write drivers of the sense amplifier and write driver 213. Under control of the control logic 230, for example, in response to a column address transferred from the control logic 230, the second gating circuit 214 may electrically connect sense amplifiers corresponding to the column address from among the plurality of sense amplifiers with the first gating circuit 220 (e.g., in the read operation) and may electrically connect write drivers corresponding to the column address from among the plurality of write drivers with the first gating circuit 220 (e.g., in the write operation).

The first gating circuit 220 may be connected with the plurality of banks 210. Under control of the control logic 230, for example, in response to a bank address transferred from the control logic 230, the first gating circuit 220 may output, as a data signal DQ, data transferred from a bank corresponding to the bank address from among the plurality of banks 210 to an external device (not explicitly shown, but implied) in synchronization with a data strobe signal DQS (e.g., in the read operation). The first gating circuit 220 may receive data as the data signal DQ from the external device in response to the data strobe signal DQS and may transfer the received data to the bank corresponding to the bank address from among the plurality of banks 210 (e.g., in the write operation).

The control logic 230 may receive a command and address CA and a clock signal CLK from the external device. The control logic 230 may control the plurality of banks 210 and the first gating circuit 220 in response to the command of the command and address CA. The control logic 230 may extract the bank address, the row address, and the column address from the address of the command and address CA. The control logic 230 may transfer the bank address to the first gating circuit 220, may transfer the row address to the row decoder 212, and may transfer the column address to the second gating circuit 114.

The control logic 230 may generate an internal clock signal(s) for controlling internal operation timings from the clock signal CLK. The control logic 230 may control the plurality of banks 210 and the first gating circuit 220 in synchronization with the internal clock signal(s). The control logic 230 may generate the data strobe signal DQS to be output to the external device from the clock signal CLK.

The control logic 230 may receive various control signals from the external device and may output various control signals to the external device. In an embodiment, the plurality of banks 210 may be classified into a plurality of bank groups, and a gating circuit (e.g., a third gating circuit) for selecting the plurality of bank groups may be added. The control logic 230 may further extract a bank group address for selecting a bank group through the third gating circuit from the address of the command and address CA.

The control logic 230 may include repair logic 231. The repair logic 231 may store repair information. After the electronic device 200 is manufactured, the device may be tested to determine whether the memory cells of the memory cell arrays 211 are defective. A defective row including a defective cell may be replaced with a redundant row. The repair logic 231 may store address information of the defective row and address information of the corresponding redundant row. When a row address included in the command and address CA corresponds to the defective row, the repair logic 231 may replace the address of the defective row with an address of a relevant redundant row.

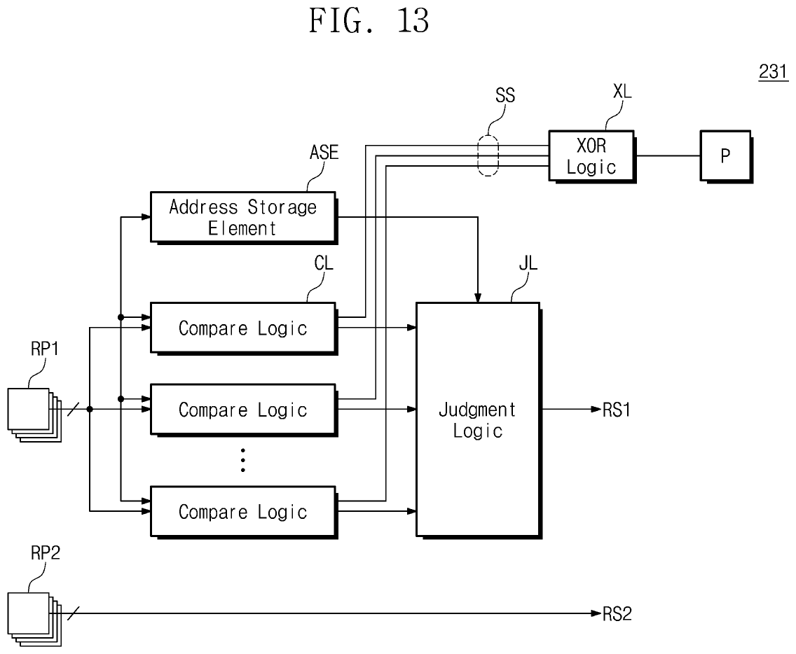

FIG. 13 is a diagram illustrating an example of the repair logic 231 of the illustrative electronic device 200 shown in FIG. 12, according to one or more embodiments. Referring to FIGS. 12 and 13, the electronic device 200 may receive a row address through first row address pads RP1 and second row address pads RP2.

The repair logic 231 may receive some bits of the row address through the first row address pads RP1. For example, the bits of the row address received through the first row address pads RP1 may be upper bits including a most significant bit (MSB).

The repair logic 231 may include an address storage element ASE, compare logic CL (which may be implemented using multiple compare logic units as shown, or as a single compare logic unit), judgment logic JL, and XOR logic XL.

The address storage element ASE may store some bits of the defective row (e.g., bits corresponding to the first row address pads RP1) and some bits of the row address of the redundant row corresponding to the defective row (e.g., bits corresponding to the first row address pads RP1).

The compare logic CL may compare bits of the row address received through the first row address pads RP1 with the portion of bits of the row address of the defective row. The compare logic CL may output the comparison results to the judgment logic JL.

When it is determined that the bits of the row address received through the first row address pads RP1 are matched with the portion of bits of the row address of the defective row, the judgment logic JL may output corresponding bits of the row address of the redundant row as a first row address signal RS1.

Alternatively, when it is determined that the bits of the row address received through the first row address pads RP1 are not matched with the portion of bits of the row address of the defective row, the judgment logic JL may output the bits of the row address received through the first row address pads RP1 as the first row address signal RS1.

The electronic device 200 may combine the first row address signal RS1 output from the judgment logic JL and a second row address signal RS2 output from the second row address pads RP2 in forming the entire row address.

In an embodiment, the first row address pads RP1 may receive the test pattern like the first input node I1 and the second input node I2 described with reference to FIGS. 9A to 9D. The compare logic CL may receive the test pattern from the first row address pads RP1. Each of the compare logic units CL may include a bypass storage element, a selective bypass storage element, a measure element, or a measure storage element.

The measure element or the measure storage element of each compare logic CL may transfer the input signal to the judgment logic JL in the specified function mode. The measure element or the measure storage element of each compare logic CL may transfer the input signal to the XOR logic XL as the measure signal SS in the test mode.

When one or more of the measure signals SS from the compare logic CL indicates a defect, the XOR logic XL may output a signal indicating the presence of at least one defect through a pad “P”. When all the measure signals SS indicate that there is no defect, the XOR logic XL may output a signal indicating no defect through the pad “P”. For example, the pad “P” may be used to output the output of the XOR logic XL to the external device (e.g., the ATE) in the test mode. The pad “P” may be used to exchange signals with an external host device in the specified function mode. For example, the pad “P” may be used for the electronic device 200 to exchange data signals with the external host device.

In an embodiment, the electronic device 200 may include a mode register set for setting operation details of the electronic device 200 and a test mode register set for setting test details of the electronic device 200. The ATE may send, to the test mode register set, information about a time period from a time when the test pattern is received through the first row address pads RP1 to a time when the compare logic units CL output the measure signals SS.

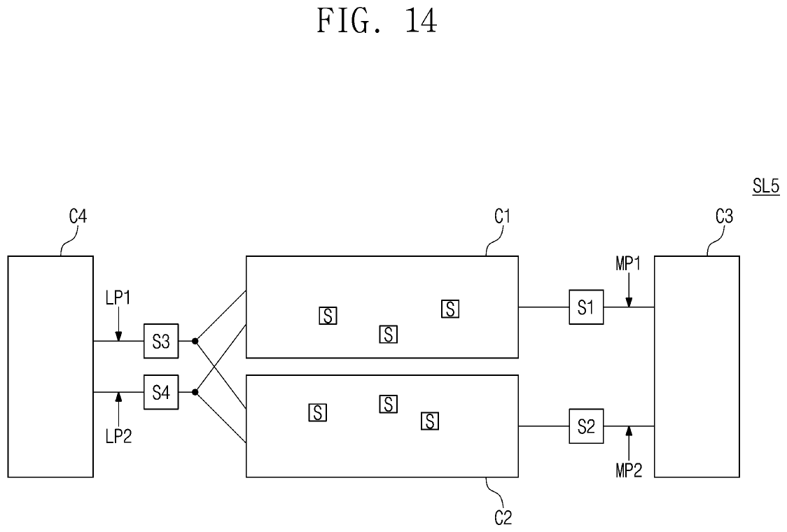

FIG. 14 is a diagram illustrating an example of a fifth source layout SL5, according to one or more embodiments. Compared to FIG. 3D, instead of the first input node I1 and the second input node I2, a fourth circuit C4 may be provided in front of the third storage element S3 and the fourth storage element S4. A point between the fourth circuit C4 and the third storage element S3 may be a first launching point LP1 that is used to receive the test signal. A point between the fourth circuit C4 and the fourth storage element S4 may be a second launching point LP2 that is used to receive the test signal.

Referring to FIGS. 1 and 14, the DFT layout generator 102 may generate a launching element at the launching point LP1 or LP2. As in the measure point MP1 or MP2, the DFT layout generator 102 may generate the launching element at the launching point LP1 or LP2.

For example, when a storage element does not exist just at the back of the launching point LP1 or LP2, the DFT layout generator 102 may insert a first type launching scan storage element. When a storage element exists just at the back of the launching point LP1 or LP2, the DFT layout generator 102 may convert a storage element to a second type launching scan storage element.

The first type launching scan storage element may include a first input, a second input, and an output. In the first operation mode (e.g., a specified function mode of performing a specified function), the first type launching scan storage element may store the signal of the first input (i.e., a specified function input) and may transfer the signal of the first input to the output (i.e., a specified function output).

In the second operation mode (e.g., a test mode), the first type launching scan storage element may store the signal of the second input (i.e., a test input) and may transfer the signal of the second input to the output.

The first type launching scan storage element may perform the specified function by transferring the signal of the first input to the output and may transfer the test pattern for the structural test by transferring the signal of the second input to the output.

The second type launching scan storage element may include a first input, a second input, and an output. In the first operation mode (e.g., a specified function mode of performing a specified function), the second type launching scan storage element may store the signal of the first input (i.e., a specified function input) and may transfer the signal of the first input to the output.

In the second operation mode (e.g., a test mode), the second type launching scan storage element may store the signal of the second input (i.e., a test input) and may transfer the signal of the second input to the output.

The second type launching scan storage element may perform the specified function by transferring the signal of the first input to the output and may transfer the test pattern for the structural test by transferring the signal of the second input to the output.

In an embodiment, the first type launching scan storage element and the second type launching scan storage element may have the same structure and may perform the same function. The first type launching scan storage element and the second type launching scan storage element may distinguish whether a constituent element is an inserted constituent element or a converted constituent element.

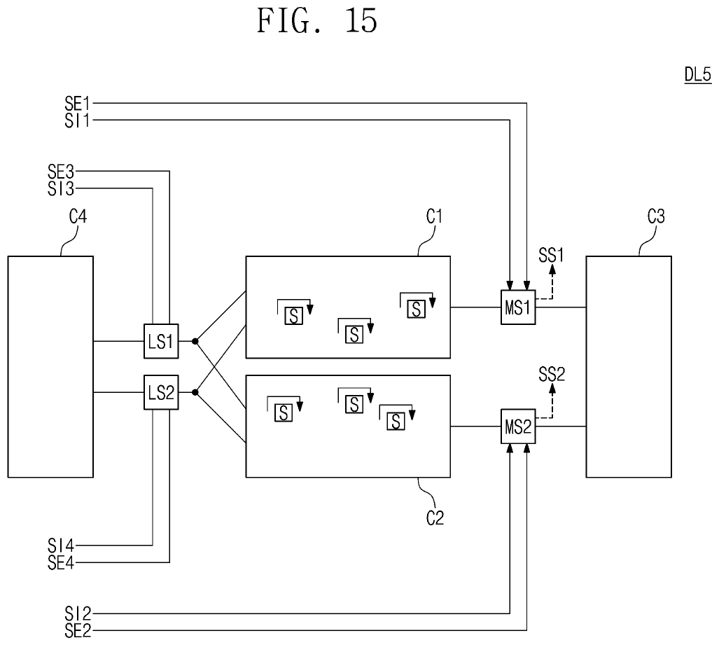

FIG. 15 is a diagram illustrating an example of a fifth DFT layout DL5, according to one or more embodiments. Referring to FIGS. 1 and 15, compared to FIG. 5D, a first launching scan storage element LS1 may be provided at a site of the first input node I1, and a second launching scan storage element LS2 may be provided at a site of the second input node I2.

The first launching scan storage element LS1 may include a first input receiving a signal from the fourth circuit C4, a second input receiving a signal from a third scan input SI3, and an output outputting a signal to the first circuit C1 and the second circuit C2.

In the first operation mode (e.g., a specified function mode), the first launching scan storage element LS1 may transfer the output of the fourth circuit C4 to the first circuit C1 and the second circuit C2. In the second operation mode (e.g., a test mode), the first launching scan storage element LS1 may transfer the output of the third scan input SI3 to the first circuit C1 and the second circuit C2. In an embodiment, the first launching scan storage element LS1 may output the signal of the third scan input SI3 when a signal of a third scan enable input SE3 is activated and may output the signal of the fourth circuit C4 when the signal of the third scan enable input SE3 is deactivated. It may be assumed that the signal of the third scan enable input SE3 and the signal of the third scan input SI3 are received from the external device through the pads.

The second launching scan storage element LS2 may include a first input receiving a signal from the fourth circuit C4, a second input receiving a signal from a fourth scan input SI4, and an output outputting a signal to the first circuit C1 and the second circuit C2.

In the first operation mode (e.g., a specified function mode), the second launching scan storage element LS2 may transfer the output of the fourth circuit C4 to the first circuit C1 and the second circuit C2. In the second operation mode (e.g., a test mode), the second launching scan storage element LS2 may transfer the output of the fourth scan input SI4 to the first circuit C1 and the second circuit C2. In an embodiment, the second launching scan storage element LS2 may output the signal of the fourth scan input SI4 when a signal of a fourth scan enable input SE4 is activated and may output the signal of the fourth circuit C4 when the signal of the fourth scan enable input SE4 is deactivated. It may be assumed that the signal of the fourth scan enable input SE4 and the signal of the fourth scan input SI4 are received from the external device through the pads.

The hybrid layout generator 104 may convert the first type launching scan storage element to a launching element and may convert the second type launching scan storage element to a launching storage element.

The launching element may include a first input, a second input, and an output. In the first operation mode (e.g., a specified function mode), the launching element may transfer the signal of the first input to the output. In the second operation mode (e.g., a test mode), the launching element may transfer the signal of the second input to the output.

The launching storage element may include a first input, a second input, and an output. In the first operation mode (e.g., a specified function mode), the launching storage element may store the signal of the first input and may output the stored signal to the output. In the second operation mode (e.g., a test mode), the launching storage element may store the signal of the second input and may transfer the stored signal to the output.

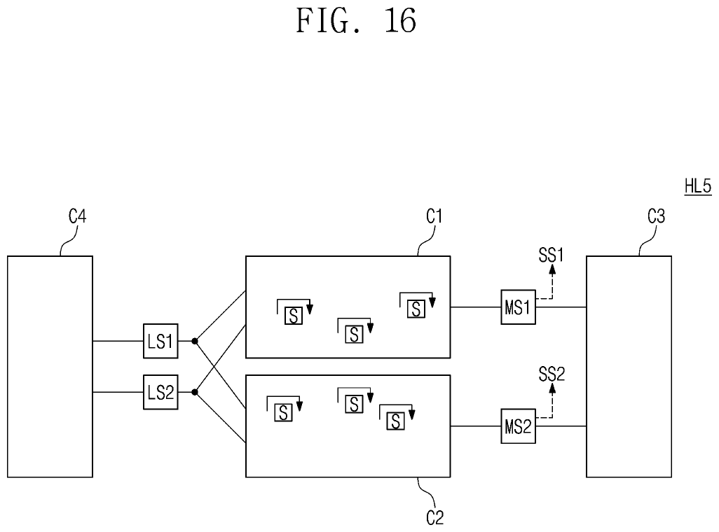

FIG. 16 is a diagram illustrating an example of a fifth hybrid layout HL5, according to one or more embodiments. Referring to FIGS. 1 and 16, compared to FIG. 9D, the first launching storage element LS1 may be provided instead of the first selective bypass storage element SB1, and the second launching storage element LS2 may be provided instead of the second selective bypass storage element SB2.

The test of the electronic device manufactured based on the fifth hybrid layout HL5 may be identical to that described with reference to FIGS. 10 and 11, except that the test pattern is input to the first launching scan storage element LS1 and the second launching scan storage element LS2 instead of the first input node I1 and the second input node I2. Thus, additional description will be omitted to avoid redundancy.

As described above, according to an embodiment of the present disclosure, the structural test is possible even in any kind of electronic device without the overhead traditionally associated with the scan chain. Accordingly, the test overhead may decrease, and the test coverage may be expanded. The embodiment of the present disclosure may be applied to any kind of electronic device, and in particular, may be applied to nonvolatile memory devices such as a flash memory, a ferroelectric memory, a phase-change memory, and a magnetic memory.

In the above embodiments, components according to the present disclosure are described by using the terms “first”, “second”, “third”, etc. However, the terms “first”, “second”, “third”, etc. may be used to distinguish components from each other and do not limit the present disclosure. For example, the terms “first”, “second”, “third”, etc. do not involve an order or a numerical meaning of any form.

In the above embodiments, components according to embodiments of the present disclosure are referenced by using blocks. The blocks may be implemented with various hardware devices, such as an integrated circuit, an application specific IC (ASIC), a field programmable gate array (FPGA), and a complex programmable logic device (CPLD), firmware driven in hardware devices, software such as an application, or a combination of a hardware device and software. Also, the blocks may include circuits implemented with semiconductor elements in an integrated circuit, or circuits enrolled as an intellectual property (IP).

It should be appreciated that when an element (e.g., circuit, block, module, etc.) is referred to as being “connected” or “coupled” to another element, it can be directly connected or coupled to the other element or intervening elements can be present. In contrast, when an element is referred to as being “directly connected” or “directly coupled” to another element, there are no intervening elements present.

According to the present disclosure, a layout of an electronic device is converted to perform a structural test in response to a test pattern generated in the process of generating the layout of the electronic device. Accordingly, an electronic device capable of performing the structural test and a method of testing an electronic device are provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A method of testing an electronic device, the method comprising:
receiving, by a computer, a circuit layout corresponding to the electronic device;
generating, by the computer, a design for test (DFT) layout from the circuit layout;
generating, by the computer, a test pattern by using an electronic design automation (EDA) tool, based at least in part on the DFT layout; and
generating, by the computer, a hybrid layout from the DFT layout, the hybrid layout being generated by removing or converting components associated with a scan chain from the DFT layout,
wherein the electronic device manufactured by using the hybrid layout is tested by using the test pattern.

2. The method of claim 1, wherein generating the DFT layout includes:
inserting a measure scan storage element at a measure point of the circuit layout,
wherein, in a first operation mode, the measure scan storage element is configured for:
storing a signal of a first input of the measure scan storage element; and
transferring the signal of the first input to a first output of the measure scan storage element, and
wherein, in a second operation mode, the measure scan storage element is configured for:
storing a signal of a second input of the measure scan storage element;
storing the signal of the first input after transferring the signal of the second input to a second output of the measure scan storage element; and
transferring the signal of the first input to the second output.

3. The method of claim 2, wherein generating the test pattern is performed in the second operation mode.

4. The method of claim 2, wherein generating the hybrid layout includes:
converting the measure scan storage element to a measure element, and
wherein the measure element is configured for:
transferring an input signal to a first output of the measure element in the first operation mode; and
transferring an input signal to a second output of the measure element in the second operation mode.

5. The method of claim 1, wherein generating the DFT layout includes:
converting a storage element at a measure point of the circuit layout to a measure scan storage element,
wherein, in a first operation mode, the measure scan storage element is configured for:
storing a signal of a first input of the measure scan storage element; and
transferring the signal of the first input to a first output of the measure scan storage element, and
wherein, in a second operation mode, the measure scan storage element is configured for:
storing a signal of a second input of the measure scan storage element;
storing the signal of the first input after transferring the signal of the second input to a second output of the measure scan storage element; and
transferring the signal of the first input to the second output.

6. The method of claim 5, wherein generating the hybrid layout includes:
converting the measure scan storage element to a measure storage element,
wherein, in the first operation mode, the measure storage element is configured for:
storing an input signal; and
transferring the input signal to a first output of measure storage element, and
wherein, in the second operation mode, the measure storage element is configured for:
storing the input signal; and
transferring the input signal to a second output of measure storage element.

7. The method of claim 1, wherein generating the DFT layout includes:
converting a storage element of an input node of the circuit layout to a bypass scan storage element,
wherein, in a first operation mode, the bypass scan storage element is configured for:
storing a signal of a first input; and
transferring the signal of the first input to a first output, and
wherein, in a second operation mode, the bypass scan storage element is configured for:
bypassing the signal of the first input to a second output; and
wherein, in a third operation mode, the bypass scan storage element is configured for:
storing a signal of a second input; and
transferring the signal of the second input to the second output.

8. The method of claim 7, wherein generating the test pattern includes:
generating a first test pattern in the second operation mode; and
generating a second test pattern in the third operation mode.

9. The method of claim 8, wherein the first test pattern is configured for testing a stuck-at fault, and the second test pattern is configured for testing a transmission delay fault.

10. The method of claim 7, wherein generating the hybrid layout includes:
converting the bypass scan storage element to a selective bypass storage element,
wherein, in the first operation mode, the selective bypass storage element is configured for:
storing a signal of an input; and
transferring the signal of the input to an output, and
wherein, in the second operation mode, the selective bypass storage element is configured for:
bypassing the signal of the input to the output, and
wherein, in the third operation mode, the selective bypass storage element is configured for:
storing the signal of the input; and
transferring the signal of the input to the output.

11. The method of claim 1, wherein the generating of the DFT layout includes:
converting at least one storage element between an input node and a measure point of the circuit layout to a bypass storage element,
wherein, in a first operation mode, the bypass storage element is configured for:
storing an input signal; and
transferring the input signal to a first output, and
wherein, in a second operation mode, the bypass storage element is configured for:
bypassing the input signal to a second output.

12. The method of claim 1, wherein the generating of the DFT layout includes:
inserting a launching scan storage element at a launching point of the circuit layout,
wherein, in a first operation mode, the launching scan storage element is configured for:
storing a signal of a first input; and
transferring the signal of the first input to an output,
wherein, in a second operation mode, the launching scan storage element is configured for:
storing a signal of a second input; and
transferring the signal of the second input to the output, and
wherein the first operation mode and the second operation mode are controlled by a signal received from an external device.

13. The method of claim 1, wherein generating the DFT layout includes:
converting a storage element of a launching point of the circuit layout to a launching scan storage element,
wherein, in a first operation mode, the launching scan storage element is configured for:
storing a signal of a first input of the launching scan storage element; and
transferring the signal of the first input to an output of the launching scan storage element,
wherein, in a second operation mode, the launching scan storage element is configured for:
storing a signal of a second input of the launching scan storage element; and
transferring the signal of the second input to the output, and
wherein the first operation mode and the second operation mode are controlled by a signal received from an external device.

14. The method of claim 13, wherein generating the hybrid layout includes:
converting the launching scan storage element to a launching storage element,
wherein, in the first operation mode, the launching storage element is configured for:
storing a signal of a first input of the launching storage element; and
transferring the signal of the first input to an output of the launching storage element,
wherein, in the second operation mode, the launching storage element is configured for:
storing a signal of a second input of the launching storage element; and
transferring the signal of the second input to the output of the launching storage element, and
wherein the first operation mode and the second operation mode are controlled by an internal signal.

15. An electronic device, comprising:
a first pad;
a second pad; and
a first circuit configured to receive a test pattern through the first pad and to output a test result corresponding to the test pattern through the second pad, in a test mode of the electronic device,
wherein the first circuit includes at least one bypass storage element,
wherein, in the test mode, the at least one bypass storage element is configured to bypass an input signal to an output of the at least one bypass storage element,
wherein, in a specified function mode of the electronic device, the at least one bypass storage element is configured to:
store the input signal; and
output the input signal to an output of the at least one bypass storage element, and
wherein the test pattern is based at least in part on a layout of the electronic device such that a structural test of the first circuit is performed.

16. The electronic device of claim 15, wherein the test pattern is generated before a final layout of the electronic device is determined.

17. The electronic device of claim 15, further comprising:
a second circuit configured to transfer a first signal to the first circuit in the specified function mode; and
a third circuit configured to receive a second signal from the first circuit in the specified function mode, and
wherein the test mode and the specified function mode are internally controlled without a signal received from an external device.

18. An electronic device, comprising:
a plurality of memory banks;
a gating circuit configured to connect one of the plurality of memory banks to an external device in response to a bank address; and
control logic configured: to receive a command and an address from the external device, the address including the bank address and a row address; to provide the bank address of the address to the gating circuit; and to provide the row address of the address to the plurality of memory banks,
wherein the control logic includes repair logic configured to:
receive a subset of bits among bits of the row address;
compare the subset of bits with repair bits; and
when the subset of bits are matched with the repair bits, replace the subset of bits with redundant bits corresponding to the repair bits,
wherein the repair logic includes:
a first circuit configured to receive a test pattern as the subset of bits and to output a test result corresponding to the test pattern, in a test mode,
wherein the first circuit includes at least one bypass storage element,
wherein, in the test mode, the at least one bypass storage element is configured to:
bypass an input signal to an output,
wherein, in a specified function mode, the at least one bypass storage element is configured to:
store the input signal; and
output the input signal to the output, and
wherein the test pattern is based at least in part on a layout of the electronic device such that a structural test of the first circuit is performed.

19. The electronic device of claim 18, wherein the first circuit includes a plurality of compare logic units,
wherein at least one of the compare logic units includes the at least one bypass storage element, and
wherein each of the compare logic units is configured to:
receive the test pattern; and
output a sub-test result corresponding to the test pattern.

20. The electronic device of claim 19, wherein the first circuit is configured to:
output a result of an XOR operation of the sub-test results of the compare logic units as the test result.
